(19) United States
(12) Patent Application Publication
(10) Pub. No.: US 2019/0288695 A1
(43) Pub. Date: Sep. 19, 2019

(54) THREE LOOP PHASE-LOCKED LOOP

(71) Applicant: TEXAS INSTRUMENTS INCORPORATED, Dallas, TX (US)

(72) Inventors: Henry YAO, Santa Clara, CA (US); Arvind SRIDHAR, Issaquah, WA (US); Sinjeet Dhanvantray PAREKH, San Jose, CA (US); Jayawardan JANARDHANAN, Issaquah, WA (US)

(21) Appl. No.: 16/233,972

(22) Filed: Dec. 27, 2018

Related U.S. Application Data
(60) Provisional application No. 62/642,031, filed on Mar. 13, 2018.

(51) Int. Cl. H03L 7/087; H03L 7/099; H03L 7/197

(52) U.S. Cl. CPC H03L 7/087; H03L 7/1974; H03L 7/099

(57) ABSTRACT

A phase-locked loop (PLL) system includes a first PLL coupled to receive a first reference clock. The PLL system also includes a second PLL coupled to receive a second reference clock. The output of the second PLL is coupled to the first PLL, and the second PLL is configured to control the first PLL. The PLL system further includes a third PLL coupled to receive an input reference clock. The output of the third PLL is coupled to the second PLL. The third PLL is configured to control the second PLL.

### RELATED APPLICATIONS

This application claims priority to U.S. Provisional Application No. 62/642,031, filed Mar. 13, 2018, which is hereby incorporated by reference.

### BACKGROUND

A phase-locked loop (PLL) generates an output clock that the PLL phase locks to an input reference clock. A PLL may include an analog phase-locked loop (APLL) to generate the output clock. The PLL also may include a digital PLL (DPLL). The DPLL includes a time-to-digital converter (TDC) that generates a digital output value that is a function of the phase difference between corresponding edges of the reference clock and a feedback clock derived from the output clock. The digital signal from the TDC is filtered by a digital loop filter and the digital loop filter's output is used to adjust a divide ratio of a frequency divider within the APLL.

### SUMMARY

A phase-locked loop (PLL) system includes a first PLL coupled to receive a first reference clock. The PLL system also includes a second PLL coupled to receive a second reference clock. The output of the second PLL is coupled to the first PLL, and the second PLL is configured to control the first PLL. The PLL system further includes a third PLL coupled to receive an input reference clock. The output of the third PLL is coupled to the second PLL. The third PLL is configured to control the second PLL.

### BRIEF DESCRIPTION OF THE DRAWINGS

For a detailed description of various examples, reference will now be made to the accompanying drawings in which:

FIG. 1 illustrates a three-loop implementation of an example phase-locked loop (PLL).

FIG. 2 shows example phase noise plots.

FIG. 3 shows the three-loop PLL with additional detail.

### DETAILED DESCRIPTION

As noted above, some PLLs include an APLL and a DPLL. A separate reference clock is provided to each of the APLL and the DPLL. The reference clock to the DPLL is the reference clock to which the PLL's output clock ultimately is to be phase-locked. The APLL's reference clock comprises a crystal oscillator (XO) clock and is referred to herein as an XO CLK. After phase-lock is initially achieved to the APLL's XO CLK, the output clock from the APLL is then phase-locked to the DPLL's reference clock. The XO CLK of the APLL has no particular phase relationship to the reference clock provided to the DPLL. Some applications for PLLs have stringent bandwidth requirements (e.g., 100 milliHertz (mHz) to 500 mHz). For narrow bandwidth PLL applications, an expensive crystal oscillator to generate the XO CLK is needed. For example, a highly accurate 50 MHz XO CLK is used whose frequency is rated to be within a 0.5 Hz range.

The disclosed examples are directed to a three-loop PLL. The three-loop PLL architecture alleviates the need to use a high frequency and high accuracy XO CLK. Instead, a relatively high frequency (e.g., 50 MHz) and low accuracy crystal oscillator is used to generate XO CLK while a relatively low frequency and high accuracy crystal oscillator is used for another of the loops. This combination of three loops and crystal oscillators effectively simulates a high frequency and high accuracy crystal oscillator at a lower cost than would be the case for a single crystal oscillator that is both high frequency and high accuracy.

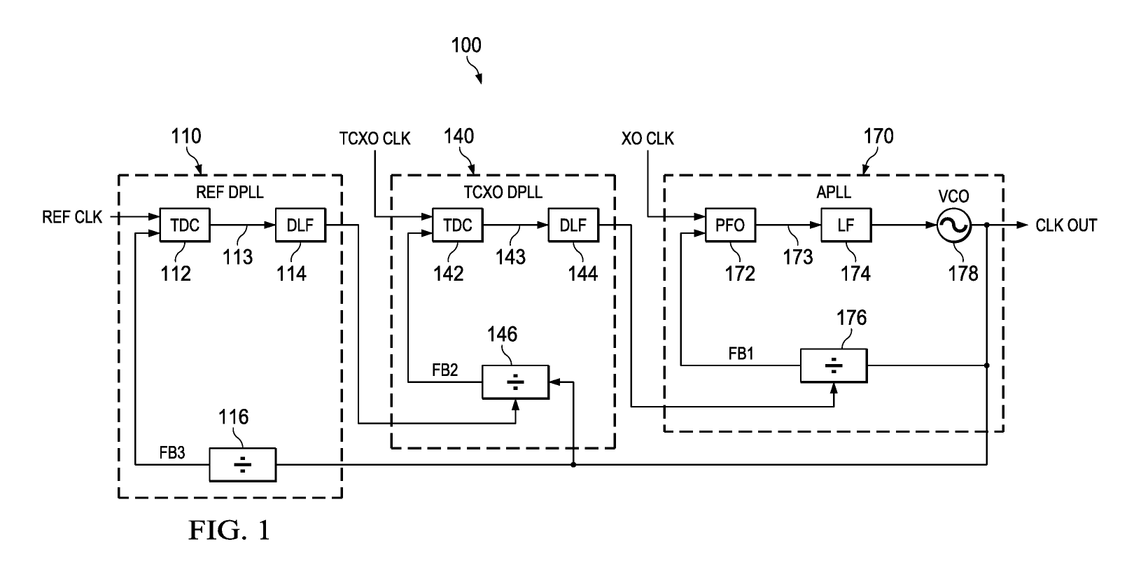

FIG. 1 shows an example of a PLL 100. The PLL 100 includes two digital PLLs (DPLL) 110 and 140 and one analog PLL (APLL) 170. The APLL 170—includes a phase-frequency detector (PFD) 172, an analog loop filter (LF) 174, a frequency divider 176 and a voltage-controller oscillator (VCO) 178. The input reference clock to the APLL is the XO CLK from a crystal oscillator. The DPLL 140 is referred to as “TCXO” DPLL 140 because its input reference clock is either a temperature-controller crystal oscillator clock (TCXO) or an oven-controller crystal oscillator clock (OCXO). The XO CLK to the APLL 170 is neither temperature-controller nor oven-controlled. The XO CLK is generated by a crystal oscillator that has relatively high frequency, but relatively low accuracy, while the TCXO CLK is generated from a crystal oscillator that has relatively low frequency, but relatively high accuracy. For example, the accuracy of TCXO CLK is greater than the accuracy of XO CLK, but the frequency of TCXO CLK is smaller than the frequency of the XO CLK. The TCXO DPLL 140 includes a time-to-digital converter (TDC) 142, a digital loop filter (DLF) 144, and a frequency divider 146. DPLL 110 receives the input reference clock (REF CLK) to the PLL 100 and thus is referred to as the REF DPLL 110.

The PFD 172 of the APLL 170 determines the phase and frequency difference between the XO CLK and a feedback clock (FB1) from the frequency divider 176. The PFD 172, which includes a charge pump, generates a control signal 173 to the LF 174. The control signal 173 is filtered by the LF 174 to generate a voltage to the VCO 178. The VCO 178 generates the output clock (CLKOUT) from the PLL with a frequency that is controlled by the voltage from the LF 174. The APLL's frequency divider 176 includes a programmable frequency divider. In one example, the frequency divider 176 includes a 9-bit integer portion (INT), a 40-bit numerator portion (NUM), a fixed 40-bit denominator portion (DEN), and a sigma-delta modulator. The sigma-delta modulator modulates the divide ration (N) of the frequency divider 176 to achieve the desired fractional ratio between the control signal 173 from the PFD 172 and the VCO output (CLKOUT). The INT and NUM values are programmable, while the denominator is fixed to, for example, 2⁴⁰ for high frequency resolution (step size) on the output of the PLL 100. The divide ratio implemented by the frequency divider 176 is: N=INT+NUM/DEN. The LF 174 may have a fixed bandwidth in some implementations or a programmable bandwidth in other implementations. In one example, the bandwidth of the LF 174 is programmable in the range of 100 kHz to 1 MHz.

Within the TCXO DPLL 140, the output of the TDC 142 is coupled to the input of the DLF 144. CLKOUT is provided to the input of the frequency divider 146 and the frequency divider's output is coupled to the TDC 142. The TDC 142 of TCXO DPLL 140 compares the phases of the TCXO/OCXO clock and a feedback clock (FB2) from the frequency divider 146 and generates a digital correction word 143 to the DLF 144 corresponding to the phase error. The correction word is then filtered by the DLF 144 and the DLF's filtered output is provided to the sigma-delta modulator of the frequency divider 176 of the APLL 170 to thereby control the divide ratio of the frequency divider 176.

The configuration of REF DPLL 110 is similar to that of TCDO DPLL 140. Within the REF DPLL 110, the output of the TDC 112 is coupled to the input of the DLF 114. CLKOUT is provided to the input of the frequency divider 116 and the frequency divider's output is coupled to the TDC 112. The TDC 112 of REF DPLL 110 compares the phases of REF CLK and a feedback clock (FB3) from the frequency divider 116 and generates a digital correction word 113 to the DLF 114 corresponding to the phase error. The correction word 113 is filtered by the DLF 114 and the filtered output from the DLF 114 is provided to a sigma-delta modulator of the frequency divider 146 of the TCXO DPLL 140 to thereby control the divide ratio of the frequency divider 146. As such, the output from the DLF 114 of the REF DPLL 110 modulates the sigma-delta modulator of the TCXO DPLL's frequency divider 146, and the output from the DLF 144 of the TCXO DPLL 140 modulates the sigma-delta modulator of the APLL's frequency divider 176.

The PLL 100 shown in FIG. 1 is a three-loop PLL. The principle of operation is as follows. After power-on reset and initialization, the APLL 170 locks the frequency of the output from the VCO 178 to the XO CLK. Once the TCXO/OCXO input clock is detected to the TCXO DPLL 140, the TCXO DPLL 140 begins lock acquisition. As noted above, the TDC 142 determines the phase difference between the TCXO/OCXO clock and FB2, and generates a corresponding digital correction word 143 to the DLF 144. The correction word is filtered by the DLF 144 and the DLF's filtered output controls the divide ratio of the frequency divider 176 of the APLL 170 until phase lock is achieved between CLKOUT and the TCXO/OCXO clock.

Once a REF CLK is provided to the REF DPLL 110, REF DPLL 110 begins lock acquisition. The TDC 112 determines the phase difference between REF CLK and FB3, and generates a corresponding digital correction word 113 to the DLF 114. The correction word is filtered by the DLF 114 and the DLF's filtered output controls the divide ratio of the frequency divider 146 of the TCXO DPLL 140. The frequency correction propagates through the TCXO DPLL 140 which then controls the APLL's frequency divider 176 until CLKOUT is ultimately locked to REF CLK.

The bandwidths of the three PLLs 110, 140, and 170 are set so as to ensure proper loop stability. In one example, the REF DPLL 110 has the lowest loop bandwidth (e.g., less than 80 Hz). The TCXO DPLL 140 has the next higher bandwidth. In one example, the bandwidth of the TCXO DPLL 140 is greater than 50 times the bandwidth of the REF DPLL 110, but less than approximately 4 KHz. The APLL 170 has the highest bandwidth of the three PLLs. In one example, the bandwidth of the APLL 170 is approximately 500 KHz. The bandwidth of the APLL can be set based on a combination of the current size of a charge pump within the PFD 172 and the bandwidth of the loop filter 174.

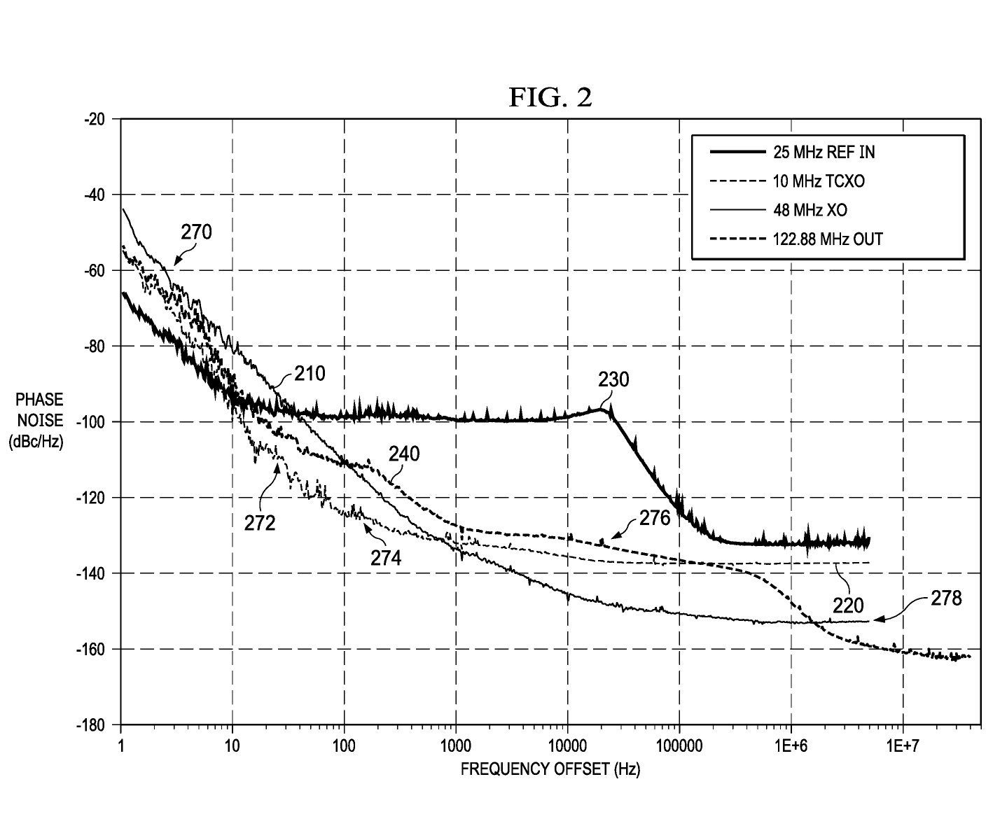

FIG. 2 shows an example of the PLL's output clock (CLKOUT) phase noise. The PLL's output clock phase noise at different frequencies is influenced by different noise contributors, such as external clock input sources (REF CLK, TCXO CLK, and XO CLK) and internal noise sources (e.g., PLLs, VCO 178), as well as the bandwidths for each of the PLLs 110, 140, and 170. In FIG. 2, the phase noise profile shown for each external clock source has been normalized to CLKOUT. Four phase noise plots are shown in FIG. 2. Plot 210 shows the phase noise for the XO CLK of the APLL 170. Plot 210 shows the phase noise for the TCXO CLK of the TCXO DPLL 140. Plot 230 shows the phase noise for REFCLK. The phase noise for CLKOUT is shown as plot 240.

As can be seen from the example phase noise plots of FIG. 2, the phase noise for XO CLK (plot 210) drops at a modest rate as frequency increases from 1 Hz to about 1 KHZ then starts to flatten at higher frequencies. The shape of phase noise plot 220 (TCXO CLK) is steeper at the lower frequencies and also flattens out but at a higher phase noise level than for plot 210. Similarly, the shape of phase noise plot 230 (REF CLK) is steeper than plots 210 and 220 at the lower frequencies and also flattens out but at a higher phase noise level than for plots 210 and 220. At frequencies (e.g., as identified by reference numeral 270) within the bandwidth of the REF DPLL 110 (e.g., 80 Hz), the REF CLK input noise contributes predominantly to the noise on CLKOUT. At frequencies (e.g., as identified by reference numeral 272) above the bandwidth of the REF DPLL 110, the REF CLK input noise is attenuated by the bandwidth of REF DPLL 140. At frequencies (e.g., as identified by reference numeral 274) below the bandwidth of the TCXO DPLL 140, the TCXO CLK noise and the noise from TDC 142 within the TCXO DPLL 140 determine the output noise on CLKOUT. Above the bandwidth of the TCXO DPLL 140 (reference numeral 276), the TCXO CLK noise is attenuated, and below the bandwidth of the APLL 170, the APLL noise dominates as the XO CLK noise contribution is much lower. At frequencies (e.g., 278) above the bandwidth of the APLL 170, the noise of VCO 178 dominates and the XO CLK noise is attenuated.

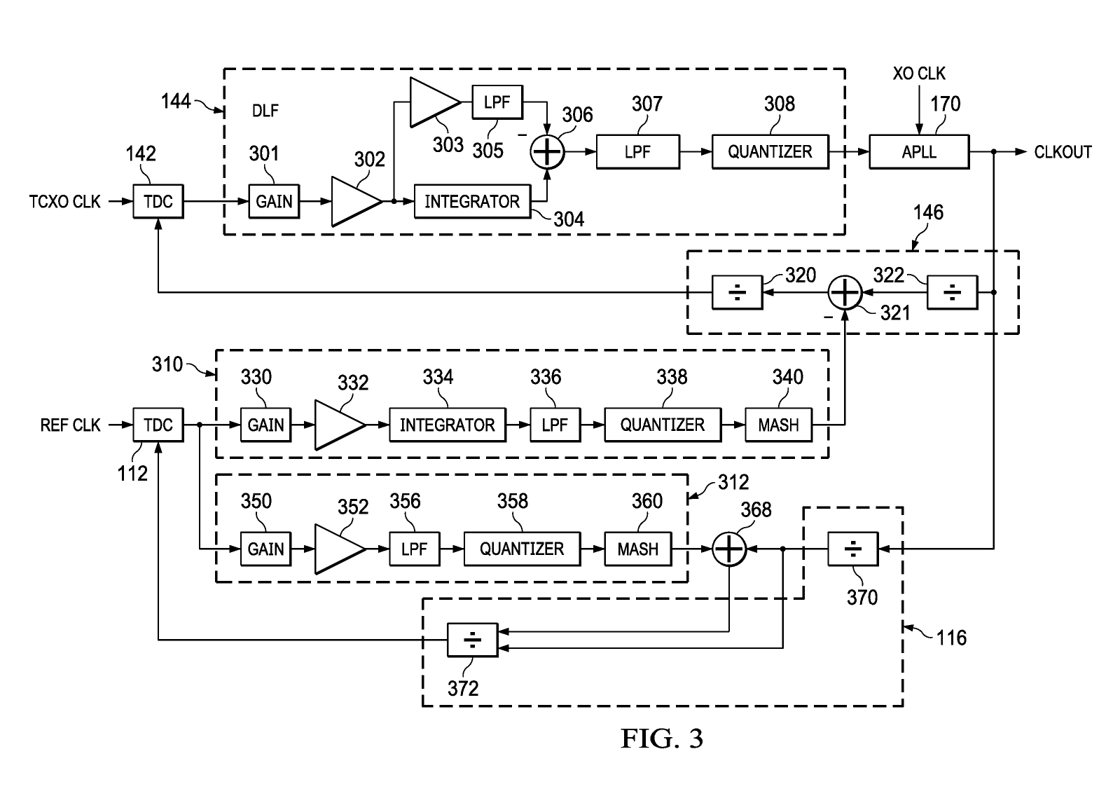

FIG. 3 shows an implementation of the PLL 100 with additional detail for the DLFs 114 and 144 and some of the frequency dividers. The DLF 144 for the TCXO DPLL 140 includes gain stages 301, 302, and 303, an integrator 304, low pass filters 305 and 307, a summer 306, and a quantizer 308. The gain stages for the TCXO DPLL 140 comprise left shift registers (left shift operations are equivalent to multiplication of digital value by an integer power of 2). The integrator 304 can be implemented as a clock delay element that adds its delayed output to an input and provides the resulting sum to the input of the delay element. That is, the integrator 304 takes sums its input with a one-clock cycle delayed version of its input. The low pass filters 305 and 307 can be implemented as digital filters. The quantizer 308 implements a mathematical divide operation that uses time averaging to generate a divide result. The quantizer 308 splits the input value into two sections. The N least significant bits comprise the remainder of the divide operation. The remaining upper bits represent the value that is to carry forward. The input remainder is summed with a one clock cycle delayed value of itself. If the output of the summed value is greater than 2 to the power of N (2^{N}), then the summed value is subtracted by 2 to power of N. The value of 1 is then added to the upper N MSB bits to generate the result of the quantizer.

The REF DPLL 110 comprises two signal paths 310 and 312 in FIG. 3. Signal 310 comprises gain stages 330 and 332, an integrator 334, a low pass filter 346, a quanitizer 338 and a Multi-stAge noise Shaper (MASH) 340. Signal path 320 comprises gain stages 350 and 352, a low pass filter 356, a quantizer 358 and a MASH 360. The frequency divider 116 comprises two frequency dividers 380 and 372. An adder 368 is included to add the output of MASH 360 tot the output of frequency divider 370.

The TCXO DPLL's frequency divider 146 is shown comprising two frequency dividers 320 and 324 separated by an adder 321. CLKOUT is provided to the input of frequency divider 322 and the output of frequency divider is added to the value from MASH 340, which functions to control the divide ratio of frequency divider 146.

CLKOUT is divided down in stages in frequency divider 116, first by frequency divider 370 and again by frequency divider 272. The output of MASH 360 is added to the divided down output of frequency divider 370 to provide a control signal to frequency divider 372 to thereby control the divide ratio of the frequency divider 372. The signal path 312 through the adder 368 implements a feed-forward zero to further help stabilize the PLL 100. The feed forward zero cancels out the phase change due to two the bandwidths of DPLLS 110 and 140 being relatively close together thereby allowing the system to emulate a single pole system. The PLL 100 is thus stable.

In this description, the term “couple” or “couples” means either an indirect or direct wired or wireless connection. Thus, if a first device couples to a second device, that connection may be through a direct connection or through an indirect connection via other devices and connections. The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A phase-locked loop (PLL) system, comprising:
a first PLL coupled to receive a first reference clock;
a second PLL coupled to receive a second reference clock, the output of the second PLL being coupled to the first PLL, and the second PLL configured to control the first PLL; and
a third PLL coupled to receive an input reference clock, the output of the third PLL coupled to the second PLL, and the third PLL configured to control the second PLL.

2. The phase-locked loop system of claim 1, wherein the first PLL comprises an analog PLL (APLL).

3. The phase-locked loop system of claim 2, wherein the second PLL comprises a digital PLL (DPLL).

4. The phase-locked loop system of claim 2, wherein the third PLL comprises a digital PLL (DPLL).

5. The phase-locked loop system of claim 1, wherein:
the second PLL comprises a digital PLL (DPLL); and
the third PLL comprises a DPLL.

6. The phase-locked loop system of claim 1, wherein:
the first PLL comprises an analog PLL;
the second PLL comprises a digital PLL (DPLL); and
the third PLL comprises a DPLL.

7. The phase-locked loop system of claim 1, wherein the first PLL includes a first frequency divider, and the second PLL is to control a divide ratio of the first frequency divider.

8. The phase-locked loop system of claim 7, wherein the second PLL includes a second frequency divider, and the third PLL is to control a divide ratio of the second frequency divider.

9. The phase-locked loop system of claim 1, wherein a frequency of the first reference clock is greater than a frequency of the second reference clock.

10. The phase-locked loop system of claim 1, wherein:
a frequency of the first reference clock is greater than a frequency of the second reference clock; and
an accuracy level of the first reference clock is smaller than an accuracy level of the second reference clock.

11. The phase-locked loop system of claim 1, wherein the first reference clock is to be generated by a crystal oscillator, and the second reference clock is to be generated by a temperature-controller crystal oscillator or an oven-controlled crystal oscillator.

12. A phase-locked loop (PLL) system, comprising:
an analog PLL coupled to receive a first reference clock;
a first digital PLL (DPLL) coupled to receive a second reference clock, the output of the first DPLL coupled to the analog PLL; and
a second DPLL coupled to receive an input reference clock, the output of the second DPLL coupled to the first DPLL.

13. The phase-locked loop system of claim 12, wherein the first DPLL is to control the analog PLL.

14. The phase-locked loop system of claim 13, wherein the second DPLL is to control the first DPLL.

15. The phase-locked loop system of claim 12, wherein the analog PLL includes a frequency divider, and the first DPLL is to control a divide ratio of the frequency divider.

16. The phase-locked loop system of claim 12, wherein the first DPLL includes a frequency divider, and the second DPLL is to control a divide ratio of the frequency divider.

17. The phase-locked loop system of claim 12, wherein:
a frequency of the first reference clock is greater than a frequency of the second reference clock; and
an accuracy level of the first reference clock is smaller than an accuracy level of the second reference clock.

18. A phase-locked loop (PLL) system, comprising:
an analog PLL coupled to receive a first reference clock;
a first digital PLL (DPLL) coupled to receive a second reference clock, the output of the first DPLL being coupled to the analog PLL, the first DPLL configured to control the analog PLL; and
a second DPLL coupled to receive an input reference clock, the output of the second DPLL coupled to the first DPLL, and the second DPLL configured to control the first DPLL.

19. The phase-locked loop system of claim 18, wherein:
the analog PLL includes a first frequency divider, and the first DPLL is to control a divide ratio of the first frequency divider; and
the first DPLL includes a second frequency divider, and the second DPLL is to control a divide ratio of the second frequency divider.

20. The phase-locked loop system of claim 18, wherein a frequency of the first reference clock is greater than a frequency of the second reference clock.
